(19) United States
(12) Patent Application Publication
(10) Pub. No.: US 2010/0175747 A1
(43) Pub. Date: Jul. 15, 2010

(54) Multilayer photovoltaic electric energy generating compound and process for its preparation and application

(75) Inventors: Stefano Segato, Vicenza (IT); Antonio Maroscia, Vicenza (IT); Fabio Cappelli, San Lazzaro di Savena (IT)

Correspondence Address: Themis Law, 7660 Fay Ave Ste H-535, La Jolla, CA, 92037, US

(73) Assignee: INNOVAMUS, Ried im Innkreis (AT)

(21) Appl. No.: 12/376,781

(22) PCT Filed: Aug. 8, 2007
(86) PCT No.: PCT/IB07/53132

§ 371 Date: Mar. 21, 2009

(30) Foreign Application Priority Data
Aug. 8, 2006 (SM) SM-A-200600027

(51) Int. Cl. H01L 31/0203; H01L 31/0224; H01L 31/18

(52) U.S. Cl. 136/256; 136/252; 136/259; 438/64; 257/E31.117

(57) ABSTRACT

A multilayer photovoltaic compound to be applied to outer surfaces of any movable and/or stationary support for absorption and conversion of light radiation into electrical energy comprising, in the following order, at least one first layer (1) designed to adhere to the surface (S) of the support (T), at least one second layer (2) of an electrically conductive material which defines an electrode, at least one third optoelectronically active layer (3) designed to absorb photons and convert them into electrical energy, at least one fourth layer (4) of an electrically conductive material which defines a counter-electrode. The first layer (1) is formed of a substantially homogeneous and continuous base material, which is chemically and mechanically inert to the other layers (2, 3, 4) to define a universal anchoring base adaptable to surfaces of any shape and size. A fifth layer (5) of an optically transparent and electronically inert material may be possibly deposited on the underlying layers (1, 2, 3, 4) to protect and encapsulate them, thereby forming a single hermetically sealed unit.

### FIELD OF THE INVENTION

The present invention is applicable to the field of photovoltaic devices for light energy utilization.

More particularly, the invention relates to a multilayer photovoltaic compound suitable to be applied to any surface and capable of absorbing solar radiation or anyway the photons impinging thereon, and convert it into electrical energy in a predetermined space position.

The invention further relates to a process for preparation and application of said multilayer compound to surfaces and walls of any type and nature.

### BACKGROUND OF THE INVENTION

Light energy, and particularly solar energy is known to be one of the cleanest and most promising renewable energy sources. Current energy requirements worldwide mostly depend on fossil fuels, particularly oil and coal, to a lesser extent on nuclear power and only minimally on other renewable energy sources, such as wind and solar power, hydropower, biofuels and biomasses.

While a reversal in consumption trends has been recently noticed in terms of the ratio of fossil fuel and nuclear energy to renewable energy, the latter, and particularly solar energy utilization systems, such as solar cells, still have a marginal share in the market, due to their high production costs, poor flexibility and difficulties in producing them on an industrial scale.

Recent problems in purchasing fossil fuels and the considerable increase of their costs, caused by international factors rather than technical problems, when combined with the vision of an unavoidable depletion of worldwide resources have raised an increasing interest in renewable energy sources, and particularly photovoltaic energy, while promoting the study of increasingly competitive, flexible and easily applicable solutions.

Multilayer solar cell-based devices are known, which use active organic components for conversion of solar energy into electrical energy, which are essentially composed of multiple layers of electronically active materials, particularly a conductive layer, e.g. containing a metal oxide, which defines a first electrode or anode, contacting a layer of a semiconductor material with electron receptor materials, in turn contacting a metal layer that defines a cathode or counter-electrode.

Examples of these prior art photovoltaic devices are disclosed in WO0186734, WO2004025746 and WO2006053127.

Due to mechanical and structural reasons, these prior art devices require the presence of a substrate, substantially in the form of a container or enclosure of a mainly rigid material, which is designed to successively receive the various layers, i.e. the electrodes and the organic components that are active in the process of transforming the impinging photons into electric charges. A basic feature of this substrate is that it has to be at least partly optically transparent, to allow the solar radiation to reach the active organic layer. By contrast, the cathode has not to be optically transparent, because solar light does not have to pass therethrough, and conversely it should be preferably reflective to maximize absorption by the active layer.

Of course, the cathode cannot itself be left exposed, to prevent any risk of damages, and will be protected by an additional closing member, also of rigid type, to form an assembly capable of being handled, in the form of a panel to be applied on the body or surface of the support, such as the wall of a building, the body of a caravan or the deckhouse of a boat.

One drawback of these prior art devices is that the substrate limits application flexibility and adaptability to the support, and requires the use of geometries imposed by the shape of the support, whereby the device cannot be applied to walls or surfaces of complex shapes.

In principle, in case of walls of complex shapes, a substrate of corresponding geometry might be preventively formed, but this would add considerable technical complexity and costs, and prevent photovoltaic devices from being used in various application conditions.

Furthermore, the useable surface of the photovoltaic device is always limited to that of the substrate, which has to be of relatively small size, wherefore the performance and efficiency of the device is accordingly reduced.

### SUMMARY OF THE INVENTION

The object of the present invention is to obviate the above drawbacks by providing a highly simple and effective multilayer photovoltaic compound.

A further object is to provide a multilayer photovoltaic compound that can be used without any substrate.

Yet another object is to provide a multilayer photovoltaic compound that can be easily and safely applied on surfaces of any shape and size.

These and other objects, as better explained hereafter, are fulfilled by a multilayer photovoltaic compound suitable to be applied to outer surfaces of any movable and/or stationary support for absorption and conversion of light radiation into electrical energy in accordance with claim 1, comprising, in the following order, at least one first bottom layer designed to adhere to the surface of the support, at least one second layer of an electrically conductive material which defines an electrode, at least one third optoelectronically active layer designed to absorb photons and convert them into electrical energy, at least one fourth layer of an electrically conductive material which defines a counter-electrode, wherein said first bottom layer is formed of a substantially homogeneous and continuous base material, which is electronically, chemically and mechanically inert to the other layers, to define a universal anchoring base adaptable to surfaces of any shape and size.

Thanks to this configuration, the compound may be prepared and applied to surfaces of any shape and size without the provision of a more or less rigid substrate of predetermined shape and size, and this will dramatically increase flexibility, ease of application and cost effectiveness of the system created therewith.

Conveniently, the base materials of these successively deposited layers are in a liquid or pasty state during the deposition process.

Thus, their application is greatly facilitated, thereby reducing both the times and costs for preparation and application.

A fifth layer of optically transparent and electronically inert material may be optionally provided, which is designed to cover and protect such succession of layers while forming a single hermetically sealed and encapsulated unit, to extend the life of the system and improve its reliability.

In a further aspect, a process is provided for preparation and application of a multilayer photovoltaic compound to an outer surface of a movable or stationary support for absorption and conversion of light radiation into electrical energy in accordance with claim 20, comprising the steps of preparing a base material to be deposited on the outer surface of the support and depositing it to form a first anchoring layer, preparing a first electrically conductive material having a specific electronic function and depositing it on the first layer to form a second electrode-defining layer, preparing an optoelectronically active material for absorbing photons and converting them into electrical energy and depositing it on said second layer to form a third layer, preparing a second electrically conductive material having a different electronic function from that of the first conductive material, and depositing it on said third layer to form a fourth counter-electrode defining layer, wherein said first layer is formed of a substantially homogeneous and continuous base material, which is electronically, chemically and mechanically inert to the other layers, to define a universal anchoring base for surfaces of any shape and size.

Thus, there will be no need to prepare the various parts of the light energy utilization device at the factory, and this clean energy source may be used in any place and under any condition by carrying out a highly simple and cost-effective process, similar in many respects to multi-coat painting of any object.

### BRIEF DESCRIPTION OF THE FIGURES

Further features and advantages of the invention will be more apparent upon reading of the detailed description of one preferred, non-exclusive embodiment of the compound and preparation and application process of the invention, which are described by way of non-limiting examples with the help of the annexed drawing, in which:

FIG. 1 is a sectional view of a portion of a multilayer photovoltaic compound according to the invention;

FIG. 2 shows an absorption spectrum of the third layer of optoelectronically active material;

FIG. 3 shows the current-voltage characteristic curve of the multilayer photovoltaic compound according to the invention, when applied to a surface.

### DESCRIPTION OF PREFERRED EMBODIMENT

Referring to the above figures, a multilayer photovoltaic compound according to the invention is shown, generally designated by P, which compound can be applied on an outer surface of any shape and size of a stationary or movable support T to form a kind of cover or paint, also having a protective and finishing function.

By way of limiting example, the support T may be a wall of a building, a ship, a plane, any vehicle or any object resting on the ground or lifted therefrom, provided that it is exposed to sunlight.

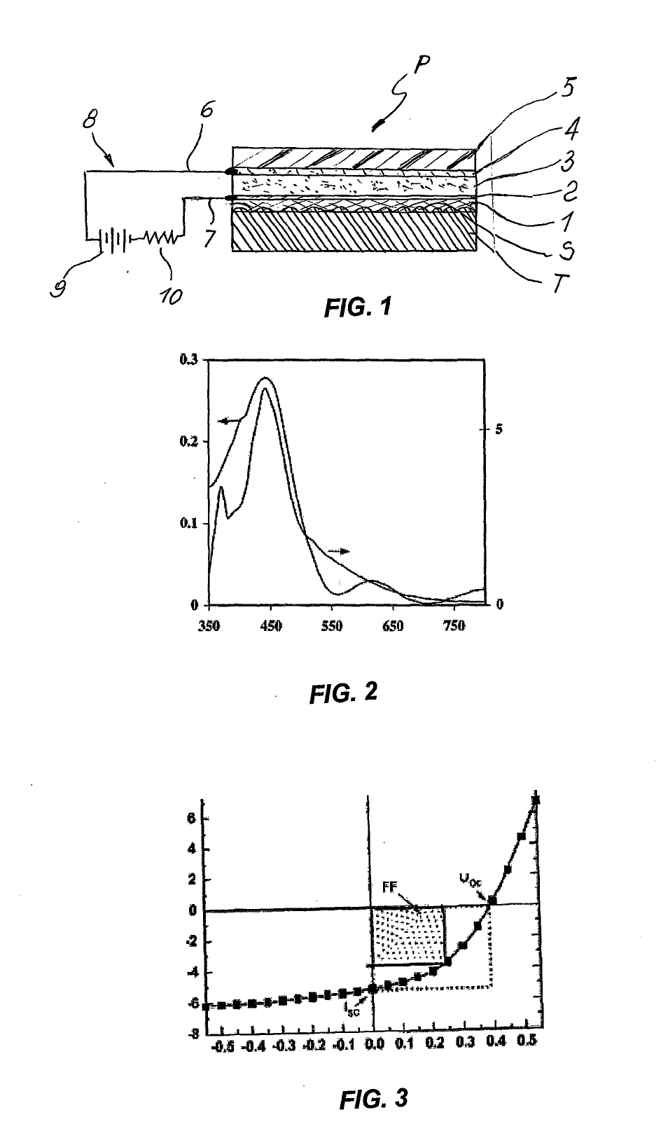

As schematically shown in FIG. 1, the photovoltaic compound P comprises a succession of layers having particular operating functions, particularly a first bottom layer 1 which is designed to contact the outer surface S of the support T, thereby forming an anchoring base for the next layers, a second layer 2 of an electrically conductive material acting as a charge collecting electrode, a third layer 3 of an optoelectronically active material which is designed to absorb photons and convert them into electric energy, a fourth layer 4 of an electrically conductive material different from the other and acting as a counter-electrode for collection of charges of opposite sign to that of the other.

According to the invention, the first layer 1 is formed of a substantially homogeneous and continuous base material, which is electronically, chemically and mechanically inert to the other layers in such a manner to define a universal anchoring base adaptable to surfaces of any shape and size.

Suitably, the base material of the layer 1 is adapted to stably adhere to the surface S of the support T, and to homogenize and planarize it to render it compatible with the electronic processes occurring in the upper layers.

It shall be noted that the first layer 1 is required because the surface S is generally not perfectly planar and is potentially subjected to mechanical instability according to change of temperature conditions as well as to external mechanical stresses. Furthermore, the surface S of the support T might be of either insulating or conductive materials, wherefore the layer 1 also has the function of electrically insulating the support from the layers of the compound P while ensuring the functionality of the various layers.

While the first layer 1 might be theoretically omitted if the base surface has its chemico-physical and morphological properties, such a layer is essential and indispensable in practice, to implement the invention under any condition.

Conveniently, the base material of the layer 1 has very low porosity and surface roughness, of the order of a few nm, to define a substantially smooth and even anchoring surface.

A material that can meet resistance requirements, while being compatible with a variety of surfaces and having a maximum roughness of the order of a few nm over large areas is polymethyl methacrylate, PMMA.

The second layer 2 which is applied on the first layer 1 is designed to act as an electrode for collection of electric charges of a predetermined sign, e.g. of positive sign. For this purpose, the material that forms the layer 2 is selected among those having a relatively high work function, of 4 eV to 6 eV. Preferably, the material shall have a work function of 4.5 eV to 5.5 eV, for effective hole collection.

A material that can meet the above solution processability requirements while being compatible with the underlying layer of polymethyl methacrilate (PMMA) is polyethylene dioxythiophene/polystyrene sulphonate (PEDOT/PSS) having a work function of about 5.2 eV. A possible alternative is colloidal gold which has interesting electronic properties (a work function of about 5.4 eV), although it significantly affects painting costs, especially on large area surfaces.

The second layer 2 shall not necessarily be optically transparent, as photonic absorption processes occur in the upper layers. The thickness of the second layer ranges from 20 nm to 1 micron depending on the material used and on its continuity characteristics when it is processed to a thin film.

The third active layer 3 has a crucial optical and optoelectronic function, because it absorbs impinging photons and generates electric charges. The material/s that form the third layer shall ensure as high sunlight absorption as possible and efficient generation of positive and negative electric charges, as well as transfer thereof towards the electrodes (second and fourth layers). The third layer shall not affect the structural and functional features of the underlying layers and shall be compatible with the fourth layer that is deposited to act as an electrode. Materials suitable for use as a third layer include poly(3-octyl(thiophene) (P3OT) and polyphenylene vinylene (PPV) derivatives. In order to improve electronic properties, as discussed above, both polythiophene derivatives and polyphenylene vinylene derivatives are conveniently combined with other materials, such as fullerenes or CdSe, CdS, ZnO, TiO2 particles.

In the most likely and convenient case of a mixture of several materials, relative concentrations and deposition conditions will be determined to optimize the optoelectronic response of the third layer.

The third layer 3 may have a thickness of 50 to 200 nm, which is determined according to the need of simultaneously maximize photonic absorption and the transfer of positive and negative charges towards the electrode and the counter-electrode.

Examples of PPV derivatives include poly[2-methoxy, 5-(2′-ethylhexoxy)-1,4-phenylenevinylene] (MEH-PPV) and poly(2-methoxy-5-(3,7-dimethyloctoxy)-p-phenylenevinylene) (OC1C10-PPV). Another material suitable for use as an active material in the fourth layer is 2,4-bis(4-(2′thiophene-yl)phenyl)thiophene (TPTPT).

The absorption spectrum of the third layer 3 formed of organic or hybrid materials is represented in FIG. 2. The ordinate values on the left indicate the absorbance of the active organic layer 3. The curve identified by the arrow on the right indicates the charge generation efficiency as a function of the incident wavelength. The ordinate values on the right indicate the percentage charge generation efficiency per unit of incident light flux. The abscissas represent the wavelength of the incident radiation in nanometers (nm).

The fourth layer 4 acts as a counter-electrode and, besides being a good conductor, it shall have the indispensable characteristic of being optically transparent in the spectral region of solar radiation. This means that solar radiation shall pass through the fourth layer with no perturbation to reach the optoelectronically active region of the third layer.

The fourth layer 4 preferably has a low work function, of 3 eV to 4.5 eV, to promote collection of negative charges generated in the system and increase the strength of the electric field determined by the difference between the work functions of the second and fourth layers (electrode and counter-electrode).

Materials suitable for use as a fourth layer include gold, silver, aluminum and colloidal calcium. Alternatively, conductive polymers or conductive oxides may be used. In any case, the thickness of the fourth layer shall account for the absorption coefficient of the selected material, so that the degree of solar radiation absorption in the third layer is not affected. The fourth layer has a thickness of 5 to 50 nm. Such thickness is required to maintain optimal optical transparency conditions in the counter-electrode through which solar radiation is designed to pass.

The low work function of the fourth layer 4 that acts as a counter-electrode, when combined to a relatively high work function of the second layer 2 that acts as an electrode, induces an electric field of higher strength within the multilayer structure which facilitates charge separation and current collection.

These four superposed layers 1, 2, 3 and 4 form the minimal indispensable structural embodiment of the compound P to obtain a multi-coat paint system, that can be applied under any condition.

However, a fifth layer 5 may be suitably provided, having the function of protecting the above multilayer system from weather and mechanical agents and whose characteristics strictly depend on the environment in which the specific application is used.

Indispensable characteristics for the fifth layer 5 include optical transparency to solar radiation, electronic inertness and sealing properties against the most potentially harmful atmospheric agents, such as moisture and corrosive brackish solutions. A class of materials that might be used as a fifth layer includes insulating and transparent oxides with SiO2. Epoxy resins and encapsulating polymers may be used as an alternative.

Preferably, the fifth layer 5 has a thickness of 100 nm to 0.5 mm, although under particular mechanical and environmental stress conditions, the thickness of the layer 5 may be increased to a few millimeters.

Generally, the probability of generating charge transfer states and electric charge collection efficiency may be increased by using multiple materials having the function of photon absorbers, electron receptors and charge carriers to the electrodes. In this configuration, the electric field in the multilayer system is determined by the specific electronic characteristics of the active materials. The strength of the electric field is further increased by using conductive electrodes having significantly different work functions. The electrode with the high work function will collect charges of positive sign, whereas the charges of negative sign will be collected by the electrode with the low work function.

FIG. 3 shows the current-voltage diagram of the overall multilayer compound S, when applied to a surface. The ordinate values on the left indicate the current density in mA/cm2. The abscissas indicate the voltage in Volts (V) generated in the multilayer structure by the energy difference between the electronic levels of the materials being used.

The acronyms have the following meanings: ISC is short circuit current, FF is the fill factor, UOC the open circuit voltage.

In short circuit conditions the electric circuit closes and the generated current can be collected.

To this end, the second layer 2 and the fourth electrically conductive layer 4 are connected at one or more peripheral points to respective electric cables or terminals 6, 7 which are designed to be connected to an external circuit, generally designated by numeral 8, for utilizing the electric energy generated by the compound. As a non limiting example, the circuit 8 is schematically shown as a battery 9 and an electric resistor 10 connected in series.

Of course, the circuit 8 may be replaced by any device for converting direct current to alternating current and supplying it to the mains, with appropriate counter means interposed therebetween, as is applicable for traditional solar panel systems.

The foregoing description clearly shows that charge generation and electron and hole carrying processes depend both on the selection of the optically and electrically active materials and on the specific organization thereof into a multilayer structure.

In this invention, multilayer paints and components are directly applied to the surface S without using any additional support. Obviously, the surface S is not optically transparent, and the first electrode 2 that is deposited on the surface is preferably highly reflective to incident sunlight. This is consistent with the fact that the present invention uses a geometry in which solar radiation impinges on the counter electrode 4, which is necessarily transparent in as wide a spectral range as possible with respect to solar emission, and is absorbed by the active organic layer.

Furthermore, the unabsorbed radiation component is effectively reflected by the electrode 2 situated closer to the wall.

In a further essential aspect, the present invention relates to a process for preparation and application of the photovoltaic compound P.

The system of the invention combines the advantages of cost-effectiveness of production processes and compatibility with surfaces of various materials, as well as adaptability to the shape of the surface to be treated.

A peculiar feature of the present invention is that the layer deposition process is carried out using materials in a liquid or pasty state, allowing to utilize highly simple deposition techniques, i.e. using spray, paintbrush, palette-knife painting techniques or the like.

Liquid or pasty solutions therefor include solid materials diluted in appropriate solvents which are susceptible to cure or polymerize at ambient temperatures and conditions, spontaneously or by the addition of catalysts, to form successive layers of normal consistency and stiffness, like in normal multi-coat painting Suitable pigments may be further introduced in the solutions to obtain compounds having a general appearance of a predetermined desired color, to integrate the compounds with the support surface.

In one application of the present invention, the various layers are successively deposited on the surface to be treated, each with a specific function in the process of solar radiation absorption, electric charge generation and collection of the generated current.

An indispensable requirement is compatibility of the methods for processing the materials that form the various layers of the system. The main parameters to be considered while assessing the compatibility of processes and materials are deposition temperature and concentration and solubility of the existing layers.

Particularly, any process that might cause damages to the underlying layers, either due to excessively high temperatures or to interactions with solvents or reagents, shall be avoided.

The layer deposition sequence will be now described with reference to a system preparation and application embodiment, and the specific function of each layer of the structure as well as the materials that meet the relevant requirements will be hence indicated.

The first step consists in preparing a base material to be deposited on the outer surface of the support and depositing it to form a first anchoring layer 1.

Once the first layer 1 has been prepared and deposited, an electrically conductive material with a specific electronic function is prepared and deposited on the first layer 1 to form a second electrode-defining layer 2.

Then, an optoelectronically active material, adapted to absorb photons and convert them into electrical energy is prepared and deposited on the second layer 2 to form a third layer 3.

Then, another electrically conductive material with a different electronic function from that of the layer 2 is prepared and deposited on the third layer 3 to form a fourth counter-electrode defining layer 4.

It should be noted that the material selected for the first layer 1 is a substantially homogeneous and continuous base material, which is electronically, chemically and mechanically inert to the other layers to define a universal anchoring base for surfaces of supports of any shape and size.

Finally, a fifth layer 5 of an optically transparent and electronically inert material is deposited on the succession of layers 1, 2, 3, 4, to define a protective and a hermetically sealed encapsulating arrangement.

As mentioned above, all the layers 1, 2, 3, 4 and 5 are liquid or pasty solutions of solid materials in suitable solvents, which are susceptible to cure or polymerize in a spontaneous manner or using catalysts after a predetermined time.

Each layer is deposited on the underlying layer at predetermined temperature and concentration to prevent damages and/or alterations of the functions of the underlying layers and those to be deposited.

Each layer is deposited by spraying and/or spreading of the solutions of the base materials.

It is underlined that the materials listed above have been mentioned by way of example only and shall by no way limit the possibility to use different materials with similar properties.

The multilayer photovoltaic compound of the invention fulfils the intended objects and particularly the requirement of providing a highly simple and effective light energy utilization system, that requires no substrate and can be easily and safely applied on surfaces of any shape and size.

The compound and application method of the invention are susceptible to a number of changes and variants, within the inventive concept disclosed in the annexed claims. All the details thereof may be replaced by other technically equivalent parts, and the materials may vary depending on different needs, without departure from the scope of the invention.

1. A multilayer photovoltaic compound to be applied to outer surfaces of any movable and/or stationary support for absorption and conversion of light radiation into electric energy comprising, in the following order,
at least one first layer (1) designed to adhere to the surface (S) of the support (T),
at least one second layer (2) of an electrically conductive material which defines an electrode,
at least one third optoelectronically active layer (3) designed to absorb photons and convert them into electrical energy,
at least one fourth layer (4) of an electrically conductive material which defines a counter-electrode,
wherein said first layer (1) is formed of a substantially homogeneous and continuous base material, which is electronically, chemically and mechanically inert to the other layers (2, 3, 4) to define a universal anchoring base adaptable to surfaces of any shape and size.

2. Multilayer photovoltaic compound as claimed in claim 1, wherein said first layer (1) is formed of a material having very low porosity and surface roughness, of the order of a few nm, to define a substantially smooth and even anchoring surface.

3. Multilayer photovoltaic compound as claimed in claim 2, wherein the base material of said first layer (1) is selected from the group of materials comprising PMMA.

4. Multilayer photovoltaic compound as claimed in claim 1, wherein said second layer (2) defining said electrode is a film of an electrically conductive material with an electropositive potential of 4 eV to 6 eV and preferably of 4.5 eV to 5.5 eV, to facilitate collection of positive electric charges.

5. Multilayer photovoltaic compound as claimed in claim 4, wherein the base material of said second layer (2) is selected from the group comprising PEDOT/PSS and colloidal gold.

6. Multilayer photovoltaic compound as claimed in claim 5, wherein said second electrically conductive layer (2) has a thickness of 10 nm to 1.5 μm and preferably of 20 nm to 1 μm.

7. Multilayer photovoltaic compound as claimed in claim 1, wherein said third optoelectronically active layer (3) is a composite material containing nanoparticles of semiconductors and/or inorganic oxides.

8. Multilayer photovoltaic compound as claimed in claim 7, wherein said nanoparticles of semiconductors and/or oxides are selected from the group comprising P3OT, PPV derivatives, fullerenes, CdSe, CdS, ZnO, TiO2, TPTPT.

9. Multilayer photovoltaic compound as claimed in claim 8, wherein said PPV derivatives are selected from the group comprising poly[2-methoxy, 5-(2′-ethylhexoxy)-1,4-phenylenevinylene] (MEH-PPV) and poly(2-methoxy-5-(3,7-dimethyloctoxy)-p-phenylenevinylene) (OC1C10-PPV).

10. Multilayer photovoltaic compound as claimed in claim 7, wherein said third optoelectronically active layer (3) has a thickness of 30 nm to 300 nm and preferably of 50 nm to 200 nm.

11. Multilayer photovoltaic compound as claimed in claim 10, wherein the composition and thickness of said third layer (3) is determined in view of maximizing photonic absorption and charge transfer to said second layer and said fourth layer defining said electrode and said counter-electrode.

12. Multilayer photovoltaic compound as claimed in claim 1, wherein said fourth electrically conductive layer (4) defining said counter-electrode is a film of a material with an electronegative potential of 2.5 eV to 5 eV and preferably of 3 eV to 4.5 eV, to facilitate collection of negative electric charges.

13. Multilayer photovoltaic compound as claimed in claim 12, wherein said fourth electrically conductive layer (4) is optically transparent.

14. Multilayer photovoltaic compound as claimed in claim 13, wherein the base material of said fourth electrically conductive layer (4) is selected from the group of materials comprising gold, silver, aluminum, colloidal calcium, polymers and conductive oxides.

15. Multilayer photovoltaic compound as claimed in claim 13, wherein said fourth electrically conductive layer (4) has a thickness of 4 nm to 60 nm and preferably of 5 nm to 50 nm, to ensure optical transparency.

16. Multilayer photovoltaic compound as claimed in claim 1, wherein said second (2) and said fourth (4) electrically conductive layers are connected to respective electric terminals (6, 7) which are designed to be connected to an external circuit (8) for utilizing the electrical energy generated by said compound.

17. Multilayer photovoltaic compound as claimed in claim 1, wherein a fifth layer (5) of an optically transparent and electronically inert material is deposited on said successive underlying layers (1, 2, 3, 4) to protect and encapsulate them, thereby forming a single hermetically sealed unit.

18. Multilayer photovoltaic compound as claimed in claim 17, wherein the base material of said fifth optically transparent layer (5) is selected from the group comprising insulating oxides and SiO2.

19. Multilayer photovoltaic compound as claimed in claim 1, wherein the base materials of all said successively deposited layers (1, 2, 3, 4, 5) are in a liquid or pasty state during the deposition process.

20. A process for preparation and application of a multilayer photovoltaic compound to an outer surface of a movable or stationary support for absorption and conversion of light radiation into electrical energy as claimed in any one of the preceding claims, including the steps of:
preparing a base material to be deposited on the outer surface (S) of the support (T) and depositing it to form a first anchoring layer (1);
preparing a first electrically conductive material having a specific electronic function and depositing it on the first layer (1) to form a second electrode-defining layer (2);
preparing an optoelectronically active material for absorbing photons and converting them into electrical energy and depositing it on said second layer (2) to form a third layer (3);
preparing a second electrically conductive material having a different electronic function from that of the first conductive material, and depositing it on said third layer (3) to form a fourth counter-electrode defining layer (4);
wherein said first layer (1) is formed of a substantially homogeneous and continuous base material, which is electronically, chemically and mechanically inert to the other layers (2, 3, 4) to define a universal anchoring base for surfaces of supports of any shape and size.

21. Process as claimed in claim 20, wherein a fifth layer (5) of an optically transparent and electronically inert material is deposited on said succession of first to fourth layers (1, 2, 3, 4), to define a protective and a hermetically sealed encapsulating arrangement.

22. Process as claimed in claim 20, wherein said layers are liquid or pasty solutions of solid materials in suitable solvents.

23. Process as claimed in claim 22, wherein said solutions are selected among those that are susceptible of curing or polymerizing spontaneously or by using catalysts.

24. Process as claimed in claim 20, wherein each layer is deposited on the underlying layer at predetermined temperature and concentration to prevent damages and/or alterations of the functions of the underlying layers and those to be deposited.

25. Process as claimed in claim 20, wherein each layer is deposited by spraying and/or spreading of the solutions of the base materials.
